(19) United States
(12) Patent Application Publication
(10) Pub. No.: US 2008/0093700 A1
(43) Pub. Date: Apr. 24, 2008

(54) SEMICONDUCTOR DEVICE AND METHOD FOR OPERATING THE SAME

(75) Inventor: Chih-Jen Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu (TW)

(21) Appl. No.: 11/551,248

(22) Filed: Oct. 20, 2006

(51) Int. Cl. H01L 29/00

(52) U.S. Cl. 257/500

(57) ABSTRACT

A method for operating a semiconductor device is described, the semiconductor device including a high-voltage device and a control circuit coupled to each other on a single chip and the high-voltage device including a source, a drain and a gate. This method applies a drain voltage of about 20V or higher to the drain while the gate and the source are floated, such that the high-voltage device self-turns on to produce a current from the drain to the source charging up the source and forming a source voltage. The source voltage serves as a power source of the control circuit, and the control circuit is driven when the source voltage is higher than the threshold voltage thereof.

### BACKGROUND OF THE INVENTION

1. Field of Invention

The present invention relates to a semiconductor device and operation thereof, and more particularly to a high-voltage device and a method for operating the same.

2. Description of Related Art

With the great development in IC technology, semiconductor transistors are used more and more widely. In products such as refrigerators, lamps, vehicle electronic devices and image displays, high-voltage (HV) devices that can sustain high voltage are needed. In addition, to provide different voltages for driving different electronic apparatuses and to lower the manufacturing cost, it is feasible to fabricate high-voltage devices and low- voltage devices simultaneously on a single chip.

A typical HV device includes an isolation layer to increase the distance between the S/D and the gate and thereby lower the lateral electric field in the channel, while the drift region under the isolation layer may be lightly doped to further lower the field. Consequently, the device is not broken down under a certain high voltage.

However, for the depth of such a lightly doped drift region is limited, the width of the same usually has to be increased. Since the dopant concentration of the same is low, the resistance of the HV device is increased lowering the operating speed.

On the other hand, to meet some requirements in the market, a depletion-mode HV device that can self-turn on as the gate is grounded or floated is developed. Such an HV device is usually formed by lightly doping the channel region with an N-type dopant. However, this method lowers the junction breakdown voltage so that the HV device can merely sustain 200-300V and cannot be used under a higher voltage.

### SUMMARY OF THE INVENTION

Accordingly, this invention provides a semiconductor device that has a relatively higher breakdown voltage.

This invention also provides a method for operating a semiconductor device that can self-turn on as the gate is floated to drive a control circuit coupled thereto.

This invention also provides a semiconductor device that has a relatively higher breakdown voltage and can self-turn on if only a drain voltage is applied.

It is firstly noted that in this invention, the term “first/second type” is defined as a first/second conductivity type.

A semiconductor device of this invention is disposed on a single chip, including a substrate of a first type and a high-voltage device thereon. The high-voltage device includes a well of a second type, a body region of the first type, a source and a drain of the second type, an isolation structure, a top layer of the first type and a first gate. The well is located in the substrate, with a dopant concentration of about 10¹⁵/cm³ or higher. The body region is in the substrate beside the well and apart from the well. The source is in the body region, and the drain is in the well. The isolation structure is disposed in the substrate between the source and the drain and over the well. The top layer is in the substrate at top of the well and under the isolation structure. The first gate is disposed over the substrate between the source and the top layer.

According to some embodiments, the well may be apart from the body region by about 10 μm. The boundary of the well may be apart from the sidewall of the isolation structure by about 8.5 μm. The body region may overlap with the source by about 4 μm. The dopant concentration of the well may be about 10¹⁵/cm³ to 3×10¹⁵/cm³. The first gate may overlap with the well and extend over the isolation structure. In addition, the breakdown voltage of the high-voltage device may be about 600V or higher.

The above semiconductor device may further include a low-voltage (LV) device on the substrate coupled to the high-voltage device. The LV device may include two heavily doped regions of the second type in the substrate and a second gate over the substrate between the two heavily doped regions, and may further include an isolation layer between the second gate and at least one of the two heavily doped regions. The isolation layer may be disposed in symmetry between the second gate and the heavily doped regions. The breakdown voltage of the LV device may be about 30V or higher.

In addition, the first type is P-type and the second type is N-type, or the first type is N-type and the second type is P-type.

The method for operating a semiconductor device of this invention is described as follows, wherein the semiconductor device includes an HV device and a control circuit coupled to each other on a single chip and the HV device includes a source, a drain and a gate. A drain voltage of 20V or higher is applied to the drain while the gate and the source are floated, such that the HV device self-turns on to produce a current from the drain to the source charging up the source and forming a source voltage. The source voltage serves as a power source of the control circuit, which is driven when the source voltage is higher than the threshold voltage thereof.

In the above method, the control circuit may feed back a signal to the gate after being driven, wherein the signal may include a clock signal. The breakdown voltage of the HV device may be about 600V or higher. The drain voltage may be about 60V or higher. The threshold voltage may be about 0.8V or higher. Alternatively, the threshold voltage may be about 3V or higher.

In the above method, the control circuit may include a low-voltage device. The breakdown voltage of the LV device may be about 30V or higher. Alternatively, the breakdown voltage of the LV device may be about 5V or higher.

Another semiconductor device of this invention is also disposed on a single chip and includes a P-substrate having an HV device area and an LV device area, an HV device and an LV device. The HV device is disposed in the high-voltage device area, including an N-well, a P-body region, an N-type source, an N-type drain, an isolation structure, a P-type top layer and a gate. The N-well is in the P-substrate and has a dopant concentration of about 10¹⁵/cm³ to 3×10⁵/cm³. The P-body region is in the P-substrate beside the N-well and apart from the N-well. The N-type source is in the P-body region. The N-type drain is in the N-well. The isolation structure is disposed in the P-substrate between the N-type source and the N-type drain and over the N-well. The P-type top layer is in the substrate at top of the N-well and under the isolation structure. The gate is disposed over the P-substrate between the N-type source and the P-type top layer. The LV device is disposed in the LV device area and coupled to the HV device. When the N-type drain of the HV device is applied with a drain voltage of about 20V or higher while the gate and the N-type source are floated, the HV device self-turns on to produce a current from the N-type drain to the N-type source charging the source and forming a source voltage, which serves as a power source for driving the LV device.

In some embodiments, the LV device may have a function of feeding back a signal, such as a clock signal, to the gate after being driven. The breakdown voltage of the HV device may be about 600V or higher, and that of the LV device may be about 30V or higher. The drain voltage may be about 60V or higher.

In addition, the N-well may be apart from the P-body region by about 10 μm. The boundary of the N-well may be apart from the sidewall of the isolation structure by about 8.5 μm. The P-body region may overlap with the N-type source by about 4 μm. The gate may overlap with the N-well and further extend over the isolation structure.

Since the HV device in the semiconductor device of this invention includes a top layer at the top of the well of a different conductivity type, a depletion region is formed allowing the depth and dopant concentration of the well to be increased to improve the operating speed of the device. Further, since the well of the second type and the body region of the first type are separated by the substrate of the first type, the breakdown voltage of the HV device is raised.

Moreover, for the HV device in the semiconductor device of this invention self-turns on with the drain voltage and the control circuit possibly including an LV device is driven by the source voltage of the HV device, no extra power source is needed.

In order to make the aforementioned and other objects, features and advantages of the present invention comprehensible, a preferred embodiment accompanied with figures is described in detail below.

### BRIEF DESCRIPTION OF THE DRAWINGS

FIG. 1 illustrates a cross sectional view of a semiconductor device according to an embodiment of this invention.

FIG. 2 depicts a circuit diagram of a semiconductor device according to another embodiment of this invention.

### DESCRIPTION OF EMBODIMENTS

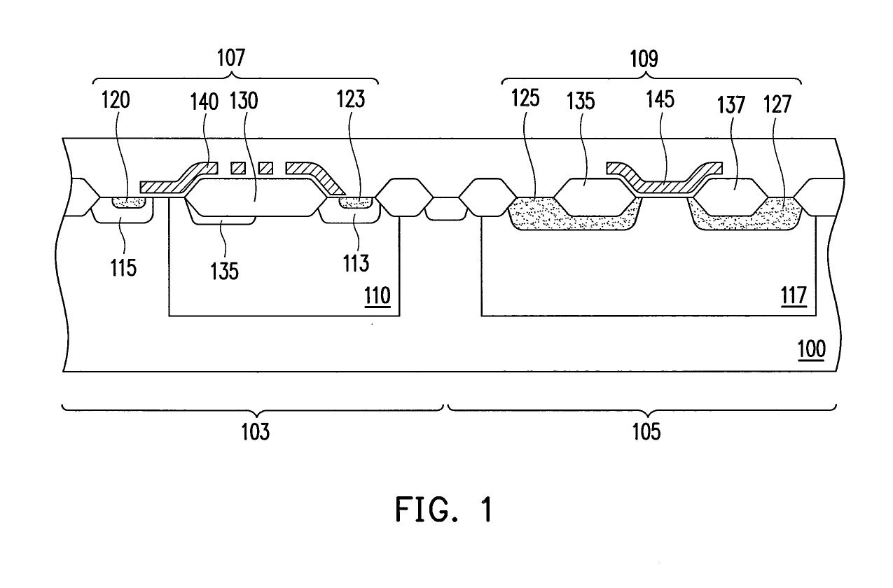

FIG. 1 depicts a cross section of a semiconductor device according to a preferred embodiment of this invention. The semiconductor device is disposed on a single chip, including a P-substrate 100 having an HV device area 103 and an LV device area 105, an HV device 107 in the HV device area 103, and an LV device 109 in the LV device area 105. The P-substrate 100 may be a P-type single-crystal silicon substrate.

The HV device 107 includes an N-well 110, a P-body region 115, an N-type source 120, an N-type drain 123, an isolation structure 130, a P-type top layer 135 and a gate 140. The breakdown voltage of the HV device 107 may be about 600V or higher.

The N-well 110 is located in the P-substrate 100, having a dopant concentration of about 10¹⁵/cm³ or higher, preferably about 10¹⁵/cm³ to 3×10¹⁵/cm³. The dopant in the N-well 110 may be phosphorous or arsenic.

The P-body region 115 is located in the P-substrate 100 beside the N-well 110 and apart from the N-well 110. That is, the N-well 110 and the P-body region 115 are separated by a portion of the P-substrate 100. In an embodiment, the distance between the N-well 110 and the P-body region 115 may be about 10 μm. The P-body region 115 is lightly doped with a P-type dopant such as boron or indium, and the dopant concentration thereof is higher than that of the P-substrate 100.

The N-type source 120 is in the P-body region 115 and the N-type drain 123 in the N-well 110. The N-type source and drain 120 and 123 are doped with an N-type dopant such as phosphorous or arsenic in a dopant concentration higher than that of the N-well 110. The N-type source 120 may overlap with the P-body region 115 by about 4 μm.

The isolation structure 130 is disposed in the P-substrate 100 between the N-type source 120 and the N-type drain 123 and over the N-well 110, possibly including an inorganic dielectric material such as silicon oxide. The distance between the sidewall of the isolation structure 130 and the boundary of the N-well 110 may be about 8.5 μm.

The P-type top layer 135 is disposed in the P-substrate 100 at top of the N-well 110 and under the isolation structure 130, opposite to the P-body region 115. The P-type top layer 135 and the underlying N-well 110 together form a depletion region to lower the drain voltage, so that the dopant concentration and depth of the N-well 110 are allowed to increase so as to lower the resistance of the channel and improve the operating speed.

The gate 140 is disposed over the P-substrate 100 between the N-type source 120 and the P-type top layer 135. In an embodiment, the gate 140 may overlap with the N-well 110 and further extend over the isolation structure 130, as shown in FIG. 1. The material of the gate 140 may be doped polysilicon.

The low-voltage device 109 includes two heavily N-doped regions 125 and 127 and a gate 145, while the term “low voltage” is used just for contrasting with the above-mentioned “high voltage” and such an LV device 109 might be an HV device in other applications. The breakdown voltage of the LV device 109 may be about 30V or higher, or alternatively be about 5V or higher, depending on the real requirements.

The heavily N-doped regions 125 and 127 are located in the P-substrate 100 as a source and a drain of the LV device 109. In an embodiment, the LV device 109 further includes an N-well 117 in the P-substrate 100, in which the heavily N-doped regions 125 and 127 are formed through phosphorous or arsenic ion implantation.

The gate 145 of the LV device 109 is disposed over the P-substrate 100 between the two heavily N-doped regions 125 and 127, possibly including doped polysilicon.

Between the gate 145 and the heavily N-doped regions 125 and 127 respectively as a source and a drain, two isolation layers 135 and 137 may be disposed in symmetry. It is also possible to form an isolation layer only between the gate 145 and the source 125 but not between the gate 145 and the drain 127.

It is noted that the conductivity types of the above parts of the semiconductor device are just exemplary and may be inverted simultaneously. More specifically, the conductivity type of all P-type parts may be changed to N-type while that of all N-type parts to P-type, with the geometrical structure of the device kept unchanged.

Since the HV device 107 in the above semiconductor device includes a P-type top layer 135 at top of the N-well 110 and under the isolation structure 130, a depletion region is formed allowing the depth and dopant concentration of the N-well 110 to be increased so as to improve the operating speed of the semiconductor device.

Moreover, since the N-well 110 and the P-type body region 115 are separated by a portion of the P-substrate 110, the breakdown voltage of the HV device can be raised up to about 600V or higher.

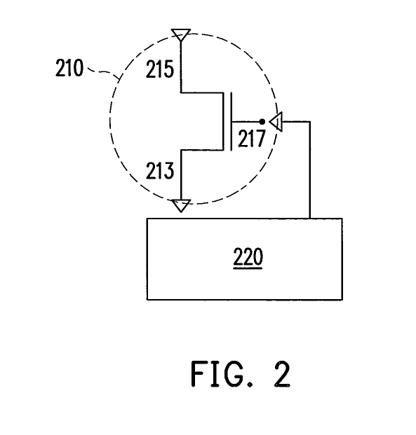

A method of operating a semiconductor device according to another embodiment of this invention is described below in reference of FIG. 2 that depicts a circuit diagram of the semiconductor device. Referring to FIG. 2, an HV device 210 is coupled to a control circuit 220, including a source 213, a drain 215 and a gate 217 and having the same structure of the HV device 107 mentioned above. The control circuit 220 may include an LV device, such as the above-mentioned LV device 109.

The operating method may include applying a drain voltage of about 20V or higher to the drain 215 while the gate 217 and the source 213 are floated. The drain voltage is coupled to the gate 217 through the N-well 110 (FIG. 1) so that the HV device 210 self-turns on to produce a current from the drain 215 to the source 213 charging the source 213 and forming a source voltage thereat. In certain cases, the drain voltage is about 60V or higher.

The source voltage of the HV device 210 serves as a power source of the control circuit 220. As the source voltage exceeds the threshold voltage of the control circuit 220, the control circuit 220 is driven to work. The threshold voltage may be about 0.8V or higher, or alternatively be 3V or higher. In some cases, the control circuit 220 has a function of feeding back a signal to the gate 217 of the HV device 210 to control the On/Off state of the same. The signal may include a clock signal that is input to the gate 217 periodically. It is particularly noted that the above voltage values are just exemplary but are not intended to limit the scope of this invention.

Accordingly, the HV device 210 and the control circuit 220 can be driven by simply applying a drain voltage to the drain 215 of the HV device 210. Such a circuit design and the corresponding operating method can simplify the IC structure and the power management. In addition, since the breakdown voltage of the HV device 210 can be raised to about 600V or higher, the semiconductor device is applied more widely.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A semiconductor device that is disposed on a single chip, comprising:
a substrate of a first type; and
a high-voltage device on the substrate, comprising:
a well of a second type in the substrate, having a dopant concentration of about 10¹⁵/cm³ or higher;
a body region of the first type in the substrate beside the well and apart from the well;
a source of the second type in the body region;
a drain of the second type in the well;
an isolation structure in the substrate between the source and the drain and over the well;
a top layer of the first type in the substrate at top of the well and under the isolation structure; and
a first gate over the substrate between the source and the top layer.

2. The semiconductor device of claim 1, wherein the well is apart from the body region by about 10 μm.

3. The semiconductor device of claim 1, wherein a boundary of the well is apart from a sidewall of the isolation structure by about 8.5 μm.

4. The semiconductor device of claim 1, wherein the body region overlaps with the source by about 4 μm.

5. The semiconductor device of claim 1, wherein the dopant concentration of the well is about 10¹⁵/cm³ to 3×10⁵/cm³.

6. The semiconductor device of claim 1, wherein the first gate overlaps with the well and extends over the isolation structure.

7. The semiconductor device of claim 1, wherein a breakdown voltage of the high-voltage device is about 600V or higher.

8. The semiconductor device of claim 1, further comprising a low-voltage device disposed on the substrate and coupled to the high-voltage device, the low-voltage device comprising:
two heavily doped regions of the second type in the substrate; and
a second gate over the substrate between the two heavily doped regions.

9. The semiconductor device of claim 8, further comprising an isolation layer between the second gate and at least one of the two heavily doped regions.

10. The semiconductor device of claim 9, wherein the isolation layer is disposed symmetrically between the second gate and the two heavily doped regions.

11. The semiconductor device of claim 8, wherein a breakdown voltage of the low-voltage device is about 30V or higher.

12. The semiconductor device of claim 1, wherein the first type is P-type and the second type is N-type.

13. The semiconductor device of claim 1, wherein the first type is N-type and the second type is P-type.

14. A method for operating a semiconductor device that includes a high-voltage device and a control circuit coupled to each other on a single chip, wherein the high-voltage device includes a source, a drain and a gate, the method comprising:
applying a drain voltage of about 20V or higher to the drain while the gate and the source are floated, such that the high voltage device self-turns on to produce a current from the drain to the source charging up the source and forming a source voltage; and
using the source voltage as a power source of the control circuit, the control circuit being driven when the source voltage is higher than a threshold voltage thereof.

15. The method of claim 14, wherein the control circuit feeds back a signal to the gate after being driven.

16. The method of claim 15, wherein the signal comprises a clock signal.

17. The method of claim 14, wherein a breakdown voltage of the high-voltage device is about 600V or higher.

18. The method of claim 14, wherein the drain voltage is about 60V or higher.

19. The method of claim 14, wherein the threshold voltage is about 0.8V or higher.

20. The method of claim 14, wherein the threshold voltage is about 3V or higher.

21. The method of claim 14, wherein the control circuit comprises a low-voltage device.

22. The method of claim 21, wherein a breakdown voltage of the low-voltage device is about 30V or higher.

23. The method of claim 21, wherein a breakdown voltage of the low-voltage device is about 5V or higher.

24. A semiconductor device that is disposed on a single chip, comprising:
a P-substrate, including a high-voltage device area and a low-voltage device area;
a high-voltage device disposed in the high-voltage device area, comprising:
a N-well in the P-substrate, having a dopant concentration of about 10¹⁵/cm³ to 3×10¹⁵/cm³;
a P-body region in the P-substrate beside the N-well and apart from the N-well;
an N-type source in the P-body region;
an N-type drain in the N-well;
an isolation structure in the P-substrate between the N-type source and the N-type drain and over the N-well;
a P-type top layer in the substrate at top of the N-well and under the isolation structure; and
a gate over the P-substrate between the N-type source and the P-type top layer; and
a low-voltage device, disposed in the low-voltage device area and coupled to the high-voltage device,
wherein when the N-type drain of the high-voltage device is applied with a drain voltage of about 20V or higher while the gate and the N-type source are floated, the high-voltage device self-turns on to produce a current from the N-type drain to the N-type source charging the source and forming a source voltage thereat, the source voltage serving as a power source for driving the low-voltage device.

25. The semiconductor device of claim 24, wherein the low-voltage device has a function of feeding back a signal to the gate after being driven.

26. The semiconductor device of claim 25, wherein the signal comprises a clock signal.

27. The semiconductor device of claim 24, wherein a breakdown voltage of the high-voltage device is about 600V or higher.

28. The semiconductor device of claim 24, wherein a breakdown voltage of the low-voltage device is about 30V or higher.

29. The semiconductor device of claim 24, wherein the drain voltage is about 60V or higher.

30. The semiconductor device of claim 24, wherein the N-well is apart from the P-body region by about 10 μm.

31. The semiconductor device of claim 24, wherein a boundary of the N-well is apart from a sidewall of the isolation structure by about 8.5 μm.

32. The semiconductor device of claim 24, wherein the P-body region overlaps with the N-type source by about 4 μm.

33. The semiconductor device of claim 24, wherein the gate overlaps with the N-well and extends over the isolation structure.
